(19) United States
(12) Patent Application Publication
(10) Pub. No.: US 2002/0132185 A1
(43) Pub. Date: Sep. 19, 2002

(54) Copolymer photoresist with improved etch resistance

(75) Inventors: Robert D. Allen, San Jose, CA (US); Phillip Joe Brock, Sunnyvale, CA (US); Richard Allen DiPietro, San Jose, CA (US); Hiroshi Ito, San Jose, CA (US); Pushkara Rao Varanasi, Poughkeepsie, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 10/141,482

(22) Filed: May 8, 2002

Related U.S. Application Data
(63) Continuation-in-part of application No. 09/566,397, filed on May 5, 2000.

(51) Int. Cl. G03F 7/004; G03C 1/73

(52) U.S. Cl. 430/270.1; 430/905; 430/910; 430/914; 430/325; 430/326; 525/191; 525/105

(57) ABSTRACT

Improved resolution photoresist compositions which are capable of high resolution lithographic performance using 193 nm imaging radiation (and possibly also with other imaging radiation) are obtained by use of imaging copolymers which are improvements over known alternating copolymer-based photoresists. The copolymers are characterized by the presence of an alkyl-functionalized cyclic olefin third monomeric unit which enhances the resolution of the photoresist. The performance of the compositions may be further enhanced by the use of bulky acid-labile protecting groups on the imaging copolymer.

### CROSS-REFERENCE TO RELATED APPLICATIONS

This application is a continuation-in-part of U.S. patent application Ser. No. 09/566,397, filed May 5, 2000, now ______.

Related applications are: U.S. patent application Ser. No. 09/266,342, filed Mar. 11, 1999, now ______, titled “Photoresist Compositions with Cyclic Olefin Polymers and Additive”; U.S. patent application Ser. No. 09/266,343, filed Mar. 11, 1999, now ______, titled “Photoresist Compositions with Cyclic Olefin Polymers and Hydrophobic Non-Steroidal Alicyclic Additives”; U.S. patent application Ser. No. 09/266,341, filed Mar. 11, 1999, now ______, titled “Photoresist Compositions with Cyclic Olefin Polymers and Hydrophobic Non-Steroidal Multi-Alicyclic Additives”; and U.S. patent application Ser. No. 09/266,344, filed Mar. 11, 1999, now ______ titled “Photoresist Compositions with Cyclic Olefin Polymers and Saturated Steroid Additives”. The disclosures of the above applications are incorporated herein by reference.

### BACKGROUND OF THE INVENTION

In the microelectronics industry as well as in other industries involving construction of microscopic structures (e.g. micromachines, magnetoresistive heads, etc.), there is a continued desire to reduce the size of structural features. In the microelectronics industry, the desire is to reduce the size of microelectronic devices and/or to provide greater amount of circuitry for a given chip size.

The ability to produce smaller devices is limited by the ability of photolithographic techniques to reliably resolve smaller features and spacings. The nature of optics is such that the ability to obtain finer resolution is limited in part by the wavelength of light (or other radiation) used to create the lithographic pattern. Thus, there has been a continual trend toward use of shorter light wavelengths for photolithographic processes. Recently, the trend has been to move from so-called I-line radiation (350 nm) to 248 nm radiation.

For future reductions in size, the need to use 193 nm radiation appears likely. Unfortunately, photoresist compositions at the heart of current 248 nm photolithographic processes are typically unsuitable for use at shorter wavelengths.

While a photoresist composition must possess desirable optical characteristics to enable image resolution at a desired radiation wavelength, the photoresist composition must also possess suitable chemical and mechanical properties to enable transfer to the image from the patterned photoresist to an underlying substrate layer(s). Thus, a patternwise exposed positive photoresist must be capable of appropriate dissolution response (i.e. selective dissolution of exposed areas) to yield the desired photoresist structure. Given the extensive experience in the photolithographic arts with the use of aqueous alkaline developers, it is important to achieve appropriate dissolution behavior in such commonly used developer solutions.

The patterned photoresist structure (after development) must be sufficiently resistant to enable transfer of the pattern to the underlying layer(s). Typically, pattern transfer is performed by some form of wet chemical etching or ion etching. The ability of the patterned photoresist layer to withstand the pattern transfer etch process (i.e., the etch resistance of the photoresist layer) is an important characteristic of the photoresist composition.

While some photoresist compositions have been designed for use with 193 nm radiation, these compositions have generally failed to deliver the true resolution benefit of shorter wavelength imaging due to a lack of performance in one or more of the above mentioned areas. One photoresist platform which has been proposed relies on so-called alternating copolymers of anhydride and cyclic olefin monomers having acid-labile functionality. Examples of such photoresists are described in U.S. Patent Nos. 5,843,624 and 6,048,664. The entire disclosures of these patents are incorporated herein by reference. While these compositions have generated some interest, they generally do not provide strong etch resistance and may have shelf life sensitivity. Thus, there remains a desire for improved photoresist compositions useful in 193 nm lithography.

### SUMMARY OF THE INVENTION

The invention provides photoresist compositions which are capable of high resolution lithographic performance using 193 nm imaging radiation (and possibly also with other imaging radiation). The photoresist compositions of the invention possess an improved combination of imageability, developability and etch resistance needed to provide pattern transfer at very high resolutions which are limited only by the wavelength of imaging radiation.

The invention also provides lithographic methods using the photoresist compositions of the invention to create photoresist structures and methods using the photoresist structures to transfer patterns to an underlying layer(s). The lithographic methods of the invention are preferably characterized by the use of 193 nm ultraviolet radiation patternwise exposure. The methods of the invention are preferably capable of resolving features of less than about 150 nm in size, more preferably less than about 130 nm in size without the use of a phase shift mask.

In one aspect, the invention encompasses a photoresist composition comprising: (a) an imaging copolymer, and (b) a photosensitive acid generator, the imaging copolymer comprising:

i) a monomeric unit having acid-labile moieties that inhibit solubility in aqueous alkaline solutions,

ii) a copolymerizing monomeric unit capable of undergoing free-radical copolymerization with cyclic olefin monomers, and

iii) cyclic olefin monomeric unit having the structure:

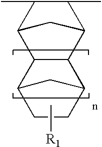

where n is zero or an integer and R₁ is selected from the group consisting of linear and/or branched C₁-C₆ alkyl groups.

The photoresist compositions of the invention preferably also contain a bulky hydrophobic additive component which is substantially transparent to 193 nm ultraviolet radiation. Monomeric unit i) is preferably derived from an unsaturated monomer, preferably selected from cyclic olefin monomers and acrylic monomers. The imaging copolymers of the invention preferably consist essentially of monomeric units i), ii) and iii). The acid-labile protecting moiety preferably includes a bulky hydrocarbon moiety.

In another aspect, the invention encompasses a method of creating a patterned photoresist structure on a substrate, the method comprising:

(a) providing a substrate having a surface layer of the photoresist composition of the invention,

(b) patternwise exposing the photoresist layer to radiation whereby portions of the photoresist layer are exposed to radiation, and

(c) contacting the photoresist layer with an aqueous alkaline developer solution to remove the exposed portions of the photoresist layer to create the patterned photoresist structure.

Preferably, the radiation used in step (b) in the above method is 193 nm ultraviolet radiation.

The invention also encompasses processes for making conductive, semiconductive, magnetic or insulative structures using the patterned photoresist structures containing the compositions of the invention.

These and other aspects of the invention are discussed in further detail below.

### DETAILED DESCRIPTION OF THE INVENTION

The photoresist compositions of the invention are generally characterized by the presence of imaging copolymers which are improvements over known alternating copolymer-based photoresists. The compositions of the invention are capable of providing improved resolution photolithographic patterns using 193 nm radiation with improved developability and pattern transfer characteristics. The invention further encompasses patterned photoresist structures containing the photoresist compositions of the invention, as well as processes for creating the photoresist structures and using the photoresist structures to form conductive, semiconductive and/or insulative structures.

The photoresist compositions of the invention generally comprise (a) an imaging copolymer, and (b) a photosensitive acid generator, the imaging copolymer comprising:

i) a monomeric unit having acid-labile moieties that inhibit solubility in aqueous alkaline solutions,

ii) a copolymerizing monomeric unit capable of undergoing free-radical copolymerization with cyclic olefin monomers, and

iii) cyclic olefin monomeric unit having the structure:

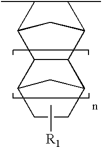

where n is zero or an integer and R₁ is selected from the group consisting of linear and/or branched C₁-C₆ alkyl groups.

Monomeric unit i) is preferably an ethylenically unsaturated monomer, more preferably a monomeric unit selected from a cyclic olefin or acrylic monomeric unit having an acid labile moiety that inhibit solubility in aqueous alkaline solutions. Examples of monomeric unit i) include the following monomeric structures illustrated by structure (I) below where R₂ represents an acid-labile protecting moiety and n is zero or some positive integer (preferably n is 0 or 1):

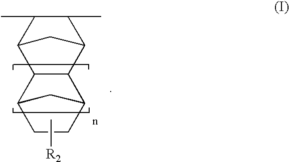

Examples of acrylic monomeric units are

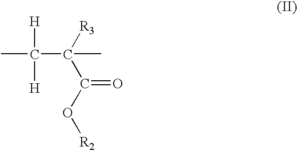

where R₂ represents an acid-labile protecting moiety. Preferred acid-labile protecting moieties are selected are selected from the group consisting of tertiary alkyl (or cycloalkyl) carboxyl esters (e.g., t-butyl, methyl cyclopentyl, methyl cyclohexyl, methyl adamantyl), ester ketals, and ester acetals. More preferably, the acid-labile protecting moiety is a bulky ester containing a C₅-C₂₀ (more preferably C₅-C₁₂) hydrocarbon moiety preferably including at least one saturated hydrocarbon ring structure. Methyl cyclopentyl carboxyl ester is a most preferred acid labile moiety. If desired, combinations of monomeric units i) having differing acid-labile protecting moieties may be used. R₃ may be hydrogen or other moiety substitutable for hydrogen without destroying the operability of the resist. R₃ is preferably selected from the group consisting of hydrogen, methyl, cyano, of trifluoromethyl.

Monomeric unit ii) may be any monomer capable of undergoing free-radical copolymerization with cyclic olefin monomers. Monomeric unit ii), in its copolymerized form, preferably does not contribute significant amounts of unsaturated carbon-carbon bonds which would excessively absorb radiation at 193 nm wavelengths. Preferably monomeric unit ii) is selected from the group consisting of maleic anhydride, maleimide, acrylate, fumarate, and acrylonitrile. More preferably, monomeric unit ii) is selected from maleic anhydride and maleimide. Most preferably, monomeric unit ii) is maleic anhydride.

Monomeric unit iii) is a cyclic olefin monomeric unit having the structure:

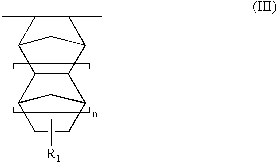

where n is zero or an integer and R₁ is selected from the group consisting of acyclic (i.e., linear and/or branched) C₁-C₆ alkyl groups. More preferably, monomeric unit iii) is selected from:

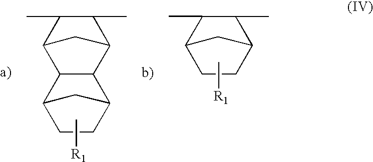

where R₁ is selected from the group consisting of linear and/or branched C₁-C₆ alkyl groups. If desired, a combination of monomeric units iii) may be used. Preferred monomeric units iii) have R₁ as a C₃-C₅ alkyl, more preferably a C₄ alkyl.

For photolithographic applications used in the manufacture of integrated circuit structures and other microscopic structures, the imaging copolymers of invention preferably comprise about 20-45 mole % of monomeric units i), more preferably about 30-40 mole %. The imaging copolymers of invention preferably comprise about 40-60 mole % of monomeric units ii), more preferably about 45-55 mole %, most preferably about 50 mole %. The imaging copolymers of the invention are preferably made by free radical polymerization which typically results in an alternating sequence of cyclic olefin (and/or acrylate) monomer and copolymerizing monomer in the imaging polymer (and therefore a 50 mole % amount of the copolymerizing monomer in the imaging copolymer). Deviation from the alternating stoichiometry may occur however depending on the polymerization conditions, the specific monomers used, etc.

The imaging copolymers of the invention preferably contain about 5-40 mole % of monomeric units iii), more preferably about 5-35 mole % of monomeric units iii), most preferably about 10-25 mole %.

The imaging copolymers of the invention preferably consist essentially of monomeric units i), ii) and iii). The imaging copolymers of the invention preferably contain sufficient monomeric unit i) such that the polymer itself is substantially insoluble in aqueous alkaline developers commonly used in lithographic applications.

In addition to the imaging copolymer, the photoresist compositions of the invention contain a photosensitive acid generator (PAG). The invention is not limited to the use of any specific PAG or combination of PAG's, that is the benefits of the invention may be achieved using various photosensitive acid generators known in the art. Preferred PAG's are those which contain reduced amounts (or preferably zero) aryl moieties. Where aryl-containing PAG is employed, the absorptive characteristics of the PAG at 193 nm may restrict the amount of PAG that can be included in the formulation.

Examples of suitable photosensitive acid generators include (but preferably with alkyl substituted for one or more of any indicated aryl moieties) onium salts such as triaryl sulfonium hexafluoroantimonate, diaryliodonium hexafluoroantimonate, hexafluoroarsenates, triflates, perfluoroalkane sulfonates (e.g., perfluoromethane sulfonate, perfluorobutane, perfluorohexane sulfonate, perfluorooctane sulfonate, etc.), substituted aryl sulfonates such as pyrogallols (e.g. trimesylate of pyrogallol or tris(sulfonate) of pyrogallol), sulfonate esters of hydroxyimides, N-sulfonyloxynaphthalimides (N-camphorsulfonyloxynaphthalimide, N-pentafluorobenzenesulfonyloxynaphthalimide), α-α′ bis-sulfonyl diazomethanes, naphthoquinone-4-diazides, alkyl disulfones and others.

The photoresist compositions of the invention may optionally further contain a bulky, hydrophobic additive (“BH” additives) which is substantially transparent to 193 nm radiation. The BH additives have generally enable and/or enhance the ability to resolve ultrafine lithographic features in response to conventional aqueous alkaline developers. The BH additives are preferably characterized by the presence of at least one alicyclic moiety. Preferably, the BH additive contains at least about 10 carbon atoms, more preferably at least 14 carbon atoms, most preferably about 14 to 60 carbon atoms. The BH additive preferably contains one or more additional moieties such as acid-labile pendant groups which undergo cleaving in the presence of acid to provide a constituent which acts to promote alkaline solubility of the radiation-exposed portions of the photoresist. Preferred BH additives are selected from the group consisting of saturated steroid compounds, non-steroidal alicyclic compounds, and non-steroidal multi-alicyclic compounds having plural acid-labile connecting groups between at least two alicyclic moieties. More preferred BH additives include lithocholates such as t-butyl-3-trifluoroacetyllithocholate, t-butyl adamantane carboxylate, and bis-adamantyl t-butyl carboxylate. Bis-adamantyl t-butyl carboxylate is a most preferred BH additive. If desired, a combination of BH additives can be used.

The photoresist compositions of the invention will typically contain a solvent prior to their application to the desired substrate. The solvent may be any solvent conventionally used with acid-catalyzed photoresists which otherwise does not have any excessively adverse impact on the performance of the photoresist composition. Preferred solvents are propylene glycol monomethyl ether acetate, cyclohexanone, and ethyl cellosolve acetate.

The compositions of the invention may further contain minor amounts of auxiliary components such as dyes/sensitizers, base additives, etc. as are known in the art. Preferred base additives are weak bases which scavenge trace acids while not having an excessive impact on the performance of the photoresist. Preferred base additives are (aliphatic or alicyclic) tertiary alkyl amines or t-alkyl ammonium hydroxides such as t-butyl ammonium hydroxide (TBAH).

The photoresist compositions of the invention preferably contain about 0.5-20 wt. % (more preferably about 3-15 wt. %) photosensitive acid generator based on the total weight of imaging copolymer in the composition. Where a solvent is present, the overall composition preferably contains about 50-90 wt. % solvent. The composition preferably contains about 1 wt. % or less of said base additive based on the total weight of acid sensitive polymer. The photoresist compositions of the invention preferably contain at least about 5 wt. % of the BH additive component based on the total weight of imaging copolymer in the composition, more preferably about 10-25 wt. %, most preferably about 10-20 wt. %.

The cyclic olefin monomers and other monomers used in the present invention may be synthesized by known techniques. The imaging copolymers are formed by free radical polymerization. Examples of suitable techniques are disclosed in U.S. Pat. Nos. 5,843,624 and 6,048,664 assigned to Lucent Technologies, Inc. mentioned above. The imaging copolymers of the invention preferably have a weight average molecular weight of about 5,000- 100,000, more preferably about 10,000- 50,000.

The photoresist compositions of the invention can be prepared by combining the imaging copolymer, PAG, optional BH additive and any other desired ingredients using conventional methods. The photoresist composition to be used in photolithographic processes will generally have a significant amount of solvent.

The photoresist compositions of the invention are especially useful for photolithographic processes used in the manufacture of integrated circuits on semiconductor substrates. The compositions are especially useful for photolithographic processes using 193 nm UV radiation. Where use of other radiation (e.g. mid-UV, 248 nm deep UV, x-ray, or e-beam) is desired, the compositions of the invention can be adjusted (if necessary) by the addition of an appropriate dye or sensitizer to the composition. The general use of the photoresist compositions of the invention in photolithography for semiconductors is described below.

Semiconductor photolithographic applications generally involve transfer of a pattern to a layer of material on the semiconductor substrate. The material layer of the semiconductor substrate may be a metal conductor layer, a ceramic insulator layer, a semiconductor layer or other material depending on the stage of the manufacture process and the desired material set for the end product. In many instances, an antireflective coating (ARC) is applied over the material layer before application of the photoresist layer. The ARC layer may be any conventional ARC which is compatible with acid catalyzed photoresists.

Typically, the solvent-containing photoresist composition is applied to the desired semiconductor substrate using spin coating or other technique. The substrate with the photoresist coating is then preferably heated (pre-exposure baked) to remove the solvent and improve the coherence of the photoresist layer. The thickness of the applied layer is preferably as thin as possible with the provisos that the thickness is preferably substantially uniform and that the photoresist layer be sufficient to withstand subsequent processing (typically reactive ion etching) to transfer the lithographic pattern to the underlying substrate material layer. The pre-exposure bake step is preferably conducted for about 10 seconds to 15 minutes, more preferably about 15 seconds to one minute. The pre-exposure bake temperature may vary depending on the glass transition temperature of the photoresist. Preferably, the pre-exposure bake is performed at temperatures which are at least 20° C. below T_{g}.

After solvent removal, the photoresist layer is then patternwise-exposed to the desired radiation (e.g. 193 nm ultraviolet radiation). Where scanning particle beams such as electron beam are used, patternwise exposure may be achieved by scanning the beam across the substrate and selectively applying the beam in the desired pattern. More typically, where wavelike radiation forms such as 193 nm ultraviolet radiation, the patternwise exposure is conducted through a mask which is placed over the photoresist layer. For 193 nm UV radiation, the total exposure energy is preferably about 100 millijoules/cm²or less, more preferably about 50 millijoules/cm² or less (e.g. 15-30 millijoules/cm²).

After the desired patternwise exposure, the photoresist layer is typically baked to further complete the acid-catalyzed reaction and to enhance the contrast of the exposed pattern. The post-exposure bake is preferably conducted at about 100-175° C., more preferably about 125-160° C. The post-exposure bake is preferably conducted for about 30 seconds to 5 minutes.

After post-exposure bake, the photoresist structure with the desired pattern is obtained (developed) by contacting the photoresist layer with an alkaline solution which selectively dissolves the areas of the photoresist which were exposed to radiation. Preferred alkaline solutions (developers) are aqueous solutions of tetramethyl ammonium hydroxide. Preferably, the photoresist compositions of the invention can be developed with conventional 0.26N aqueous alkaline solutions. The photoresist compositions of the invention can also be developed using 0.14N or 0.21N or other aqueous alkaline solutions. The resulting photoresist structure on the substrate is then typically dried to remove any remaining developer solvent. The photoresist compositions of the invention are generally characterized in that the product photoresist structures have high etch resistance. In some instances, it may be possible to further enhance the etch resistance of the photoresist structure by using a post-silylation technique using methods known in the art.

The pattern from the photoresist structure may then be transferred to the material (e.g., ceramic, metal or semiconductor) of the underlying substrate. Typically, the transfer is achieved by reactive ion etching or some other etching technique. In the context of reactive ion etching, the etch resistance of the photoresist layer is especially important. Thus, the compositions of the invention and resulting photoresist structures can be used to create patterned material layer structures such as metal wiring lines, holes for contacts or vias, insulation sections (e.g., damascene trenches or shallow trench isolation), trenches for capacitor structures, etc. as might be used in the design of integrated circuit devices.

The processes for making these (ceramic, metal or semiconductor) features generally involve providing a material layer or section of the substrate to be patterned, applying a layer of photoresist over the material layer or section, patternwise exposing the photoresist to radiation, developing the pattern by contacting the exposed photoresist with a solvent, etching the layer(s) underlying the photoresist layer at spaces in the pattern whereby a patterned material layer or substrate section is formed, and removing any remaining photoresist from the substrate. In some instances, a hard mask may be used below the photoresist layer to facilitate transfer of the pattern to a further underlying material layer or section. Examples of such processes are disclosed in U.S. Pat. Nos. 4,855,017; 5,362,663; 5,429,710; 5,562,801; 5,618,751; 5,744,376; 5,801,094; and 5,821,469, the disclosures of which patents are incorporated herein by reference. Other examples of pattern transfer processes are described in Chapters 12 and 13 of “Semiconductor Lithography, Principles, Practices, and Materials” by Wayne Moreau, Plenum Press, (1988), the disclosure of which is incorporated herein by reference. It should be understood that the invention is not limited to any specific lithography technique or device structure.

### EXAMPLE 1

An imaging copolymer was formed by free radical polymerization to achieve a copolymer of n-butyl norbornene/norbornene-methylcyclopentylester/maleic anhydride (15/35/50 mole % monomer composition). The copolymer was then formulated into a photoresist composition by dissolving the copolymer in PGMEA (15 wt. % solids), and combining with (i) bis-adamantyl ester of a di-tertiary alcohol at 17 parts by weight per 100 parts of copolymer, and (ii) a combination of perfluorooctane sulfonate (3 parts) and norbornene imido perfluorobutane sulfonate (1 part) per 100 parts of copolymer. A base additive (tetrabutylammonium hydroxide) was also added to the formulation at less than 1 part by weight per 100 parts of copolymer to achieve the final resist formulation. This resist was spin coated onto a wafer and post-apply baked (PAB) at 130° C. for 60 sec. The resist was imaged (patternwise exposed) using 193 nm radiation (50 mJ/cm²) on an ISI microstepper. After exposure, the resist was baked (PEB) at 140° C. for 90 sec. and then developed in 0.26N TMAH for 60 seconds. The resulting photoresist structure had a pattern of clean 130 nm features (nested lines and spaces). Also, the unexposed portions of the resist exhibited zero thinning in response to the developer; thus, pattern in the photoresist structure was of very high contrast.

### EXAMPLE 2

### Synthesis of Terpolymer of 5-(nbutyl)norbornene, 1-methylcyclopentyl Acrylate and Maleic Anhydride

A flask (100 mL three-neck round-bottom flask equipped with a magnetic stirrer, glass stopper, thermocouple thermometer, temperature-controlled heating mantle, and Friedrichs condenser connected to a nitrogen gas bubbler) was charged with 5-(nbutyl)-norbornene (10.71 g, 0.0713 mol), 1-methylcyclopentyl acrylate (11.0 g, 0.0713 mol), maleic anhydride (9.33 g, 0.0951 mol), and 10 mL methyl acetate. The mixture was heated to 80° C. and dimethyl 2,2′-azobisisobutyrate initiator (V-601 manufactured by Wako Pure Chemical Industries, Ltd.) (1.093 g, 0.00475 mol) added, the reaction product was nitrogen flushed and heated to reflux. After three hours, an additional portion of the initiator (1.093 g, 0.00475 mol) was added along with 10 mL of ethyl acetate, followed by nitrogen flushing and continued heating (at reflux, internal temperature of about 72° C.). The additions of initiator and ethyl acetate were repeated once more after a 3 hour interval at reflux. After all of the initiator had been added (total of 3.28 g), the mixture was heated at reflux, under nitrogen, for an additional 15 hours. The cooled reaction mixture (quite viscous) was precipitated into 3.5 L of stirred 2-propanol (IPA). The solid product was stirred for 1 hour and then was allowed to settle. The solid (orange-tan powder) was isolated by filtration onto a medium-frit glass filter funnel. The solid was washed with three 100-mL portions of 2-propanol, sucked dry in the filter funnel, and dried 60 hours in a vacuum oven at a temperature of 50-60° C. and an ultimate vacuum of less than 500 milliTorr. A total of 29.70 grams (95% based on monomer charge) of product was isolated. The polymer GPC Mw was 6672 versus polystyrene standards.

What is claimed is:

1. A photoresist composition comprising (a) an imaging copolymer, and (b) a photosensitive acid generator, said imaging copolymer comprising:
i) a monomeric unit having acid-labile moieties that inhibit solubility in aqueous alkaline solutions,
ii) a copolymerizing monomeric unit capable of undergoing free-radical copolymerization with cyclic olefin monomers, and
iii) cyclic olefin monomeric unit having the structure: 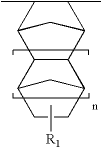
where n is zero or an integer and R₁ is selected from the group consisting of linear and/or branched C₁-C₆ alkyl groups.

2. The photoresist composition of claim 1 wherein said imaging copolymer consists essentially of said monomeric units i), ii) and iii).

3. The photoresist composition of claim 1 wherein said imaging copolymer comprises about 20-45 mole % of monomeric unit i), about 40-60 mole % of monomeric unit ii), and about 5-40 mole % of monomeric unit iii).

4. The photoresist composition of claim 1 further comprising (c) a bulky hydrophobic additive which is substantially transparent to 193 nm radiation.

5. The composition of claim 1 wherein said monomeric unit i) is selected from the group consisting of cyclic olefin monomers and acrylic monomers.

6. The composition of claim 1 wherein said monomer unit iii) consists essentially of C₁-C₆ alkyl-functionalized cyclic olefin.

7. The composition of claim 5 wherein said monomer unit i) consists essentially of acrylic monomer.

8. The composition of claim 6 wherein said alkyl-functionalized cyclic olefin is a C₄ alkyl-functionalized olefin.

9. The composition of claim 6 wherein said monomeric unit iii) is present at about 5-25 mole % based on the total of monomers in said imaging copolymer.

10. The composition of claim 1 wherein said monomeric unit i) contains an acid-labile protecting group containing a bulky C₅-C₂₀ hydrocarbon moiety.

11. The composition of claim 1 wherein said copolymerizing monomeric unit ii) is selected from the group consisting of maleic anhydrides and maleimides.

12. The composition of claim 1 wherein said photoresist composition contains at least about 0.5 wt. % of said photosensitive acid generator based on the weight of said imaging copolymer.

13. A method of forming a patterned material structure on a substrate, said material being selected from the group consisting of semiconductors, ceramics and metals, said method comprising:
(A) providing a substrate with a layer of said material,
(B) applying a photoresist composition to said substrate to form a photoresist layer on said substrate, said photoresist composition comprising (a) an imaging copolymer, and (b) a photosensitive acid generator, said imaging copolymer comprising:
i) a monomeric unit having acid-labile moieties that inhibit solubility in aqueous alkaline solutions,
ii) a copolymerizing monomeric unit capable of undergoing free-radical copolymerization with cyclic olefin monomers, and
iii) cyclic olefin monomeric unit having the structure: 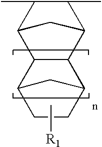
where n is zero or an integer and R₁ is selected from the group consisting of linear and/or branched C₁-C₆ alkyl groups.
(C) patternwise exposing said substrate to radiation whereby acid is generated by said photosensitive acid generator in exposed regions of said photoresist layer by said radiation,
(D) contacting said substrate with an aqueous alkaline developer solution, whereby said exposed regions of said photoresist layer are selectively dissolved by said developer solution to reveal a patterned photoresist structure, and
(E) transferring photoresist structure pattern to said material layer, by etching into said material layer through spaces in said photoresist structure pattern.

14. The method of claim 13 wherein said photoresist further comprises (c) a bulky hydrophobic additive which is substantially transparent to 193 nm radiation.

15. The method of claim 13 wherein said imaging copolymer comprises about 20-45 mole % of monomeric unit i), about 40-60 mole % of monomeric unit ii), and about 5-40 mole % of monomeric unit iii).

16. The method of claim 13 wherein said monomeric unit i) is selected from the group consisting of cyclic olefin monomers and acrylic monomers.

17. The method of claim 13 wherein said etching comprises reactive ion etching.

18. The method of claim 13 wherein at least one intermediate layer is provided between said material layer and said photoresist layer, and step (E) comprises etching through said intermediate layer.

19. The method of claim 13 wherein said radiation has a wavelength of about 193 nm.

20. The method of claim 13 wherein said substrate is baked between steps (C) and (D).
